(19) United States
(12) Patent Application Publication
(10) Pub. No.: US 2007/0200168 A1
(43) Pub. Date: Aug. 30, 2007

(54) MONOS type nonvolatile memory cell, nonvolatile memory, and manufacturing method thereof

(76) Inventors: Yoshio Ozawa, Yokohama-shi (JP); Yoshitaka Tsunashima, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/706,999

(22) Filed: Feb. 16, 2007

(30) Foreign Application Priority Data
Feb. 16, 2006 (JP) 2006-039362
Jan. 23, 2007 (JP) 2007-012942

(51) Int. Cl. H01L 29/792

(52) U.S. Cl. 257/324

(57) ABSTRACT

A MONOS type nonvolatile memory cell is structured such that a laminated insulating film which is formed by sequentially laminating a tunnel insulating layer, a charge storage insulating layer, and a charge block insulating layer is provided on a convex curved surface portion of a semiconductor substrate, and a control gate electrode is further formed thereon. A thickness of the tunnel insulating layer is set to be 4 to 10 nm, and data writing/data erasing operations are carried out by making an F-N tunneling current flow in the tunnel insulating layer.

### CROSS-REFERENCE TO RELATED APPLICATIONS

This application is based upon and claims the benefit of priority from prior Japanese Patent Applications No. 2006-039362, filed Feb. 16, 2006; and No. 2007-012942, filed Jan. 23, 2007, the entire contents of both of which are incorporated herein by reference.

### BACKGROUND OF THE INVENTION

1. Field of the Invention

The present invention relates to a nonvolatile memory cell, a nonvolatile memory, and a manufacturing method thereof, and in particular, to a MONOS type nonvolatile memory cell using an insulator as a charge storage layer, a structure of a nonvolatile memory using an array thereof, and a manufacturing method thereof. Moreover, the present invention is used for a nonvolatile memory of, for example, a NAND type, a NOR type, or the like.

2. Description of the Related Art

In a conventional nonvolatile memory using MONOS type nonvolatile memory cells and an array thereof, a three-layer laminated insulating film which is formed from a tunnel oxide film, a charge storage nitride film, and a charge block oxide film is provided on a channel region on a surface of a flat silicon substrate. Further, and a control gate electrode is further provided thereon. Conventionally, a typical film thickness of the tunnel oxide film is 2 to 3 nm.

A data writing operation to the above-described memory cells is carried out such that a high voltage is applied between the silicon substrate and the control gate electrode, and an electric charge is stored at an electric charge trap level in the charge storage nitride film by making a direct tunneling current flow in the tunnel oxide film. At this time, the charge block oxide film prevents the stored electric charge from escaping toward the control gate electrode side. In a data-retention state in which data writing has been carried out and left as it is, a so-called self electric field is generated due to the electric charge stored in the charge storage nitride film, and the stored electric charge intends to escape toward the silicon substrate side and the control gate electrode side. This escape of electric charge can be avoided by sandwiching the charge storage nitride film with the tunnel oxide film and the charge block oxide film having high potential barriers.

In the conventional memory cell described above, the three-layer laminated insulating film is provided between the silicon substrate and the control gate electrode. In order to make a direct tunneling current flow in the tunnel oxide film, in a quintessential way, it is necessary to apply a high voltage of about 10 to 20 V. Therefore, it is impossible to reduce electric power consumption. Further, due to the need of insuring a desired withstand voltage among memory cells, it is impossible to realize the miniaturization of memory cells.

Moreover, in the conventional memory cell described above, a film thickness of the tunnel oxide film is as thin as 2 to 3 nm in order to carry out a direct tunneling operation. Such a film thickness is not sufficient in order to prevent an electric charge from escaping due to a self electric field at the time of data-retention. Accordingly, when the memory cell is left for a long period after data writing, a quantity of stored electric charge is varied by escape of electric charge, which may bring about a malfunction. It is necessary to limit a quantity of stored electric charge in order to avoid the malfunction. Then, a threshold voltage window of a memory cell transistor is made narrow, which makes it impossible to achieve multi-level memory operations.

Note that, in Jpn. Pat. Appln. KOKAI Publication No. 10-22403, there is disclosed a floating gate (FG) type nonvolatile memory in which electric charge is stored in a charge storage layer formed from a conductor by making a Fower-Nordheim (F-N) tunneling current flow in a tunnel insulating film provided on a substrate having a convex curved surface. An element region is projected from an isolation region, and the projected boundary portion of the element region is rounded so as to concentrate an F-N tunneling current within a range in which dielectric breakdown is not brought about in the tunnel oxide film. As a result, the F-N tunneling current flows in the tunnel oxide film so as to be unevenly distributed.

However, there has not been disclosed a shape of the top surface of a preferred floating gate as a nonvolatile memory, i.e., a shape of a charge block insulating layer.

Moreover, the following problem has been clear from the study of the present inventor. Namely, when a charge storage layer is a conductor, a potential difference is not generated in the charge storage layer when a desired electric field is applied to a tunnel insulating layer. Thus, a great potential difference is generated in the charge block insulating layer. Accordingly, it has been found that, because it is impossible to find a great difference in the tunneling effects of the tunnel insulating layer and the charge block insulating layer, a sufficient operation speed of a nonvolatile memory cannot be obtained.

### BRIEF SUMMARY OF THE INVENTION

According to a first aspect of the present invention, there is provided a MONOS type nonvolatile memory cell comprising: a semiconductor substrate having a convex curved surface portion; a laminated insulating film which is formed of a tunnel insulating layer with a thickness of 4 to 10 nm, a charge storage insulating layer, and a charge block insulating layer, which are sequentially laminated on the convex curved surface portion; and a control gate electrode which is formed on the laminated insulating film, wherein the memory cell carries out data writing/data erasing operations by making an F-N tunneling current flow in the tunnel insulating layer.

According to a second aspect of the present invention, there is provided a method for manufacturing a MONOS type nonvolatile memory comprising: forming a plurality of convex curved surface portions on a semiconductor substrate; forming a tunnel insulating layer with a thickness of 4 to 10 nm on the each convex curved surface portion by one of a radical oxidation method and a radical nitridation method; and sequentially laminating a charge storage insulating layer, a charge block insulating layer, and a conductive layer of a control gate electrode on the tunnel insulating layer.

### BRIEF DESCRIPTION OF THE SEVERAL VIEWS OF THE DRAWING

FIG. 1A is a cross-sectional view showing a typical structure of a MONOS type nonvolatile memory cell of the present invention;

FIG. 1B is a diagram schematically showing an energy band at the time of data writing of the memory cell of FIG. 1A;

FIG. 1C is a diagram schematically showing an energy band at the time of data writing of the memory cell of FIG. 1A when a film thickness of a tunnel insulating layer is different from that of FIG. 1B;

FIG. 2A is a cross-sectional view showing a structure of a curved surface conductor in the MONOS type nonvolatile memory cell of the present invention;

FIG. 2B is a characteristic diagram showing a relationship between a relative position in a film thickness direction and a relative electric field intensity at the time of providing a potential difference between the curved surface conductors when the curved surface conductor in the MONOS type nonvolatile memory cell of FIG. 2A is a concentric cylindrical cell;

FIG. 2C is a characteristic diagram showing a relationship between a relative position in a film thickness direction and a relative electric field intensity at the time of providing a potential difference between the curved surface conductors when the curved surface conductor in the MONOS type nonvolatile memory cell of FIG. 2A is a concentric spherical cell;

FIG. 3A is a diagram showing an energy band at the time of data writing onto the memory cell of FIG. 1A;

FIG. 3B is a diagram showing an energy band at the time of data erasing from the memory cell of FIG. 1A;

FIG. 3C is a diagram showing an energy band in a data-retention state with respect to the memory cell of FIG. 1A;

FIG. 4 is a cross-sectional view showing a structure in a channel width direction of a concentric cylindrical MONOS type memory cell according to a first embodiment of the present invention;

FIG. 5A is a cross-sectional view showing a state of lines of electric force at the time of data writing onto the concentric cylindrical MONOS type memory cell according to the first embodiment;

FIG. 5B is a cross-sectional view showing a state of lines of electric force at the time of data writing onto a concentric cylindrical MONOS type memory cell according to a reference example;

FIG. 6A is a plan view of an array at a part of process of manufacturing the concentric cylindrical MONOS type memory cell of FIG. 4;

FIG. 6B is a cross-sectional view of the array in the manufacturing process following that of FIG. 6A;

FIG. 6C is a cross-sectional view of the array in the manufacturing process following that of FIG. 6B;

FIG. 6D is a cross-sectional view of the array in the manufacturing process following that of FIG. 6C;

FIG. 6E is a cross-sectional view of the array in the manufacturing process following that of FIG. 6D;

FIG. 6F is a plan view of the array in the manufacturing process following that of FIG. 6E;

FIG. 6G is a cross-sectional view of the array in the manufacturing process following that of FIG. 6F;

FIG. 6H is a cross-sectional view of the array in the manufacturing process following that of FIG. 6G;

FIG. 7A is a cross-sectional view showing a structure in a channel width direction of a concentric spherical MONOS type memory cell according to a second embodiment of the present invention;

FIG. 7B is a cross-sectional view showing a structure in a channel length direction of the concentric spherical MONOS type memory cell according to the second embodiment;

FIG. 8A is a cross-sectional view showing a structure in a channel width direction of an array at a part of process of manufacturing the concentric cylindrical MONOS type memory cell according to the second embodiment;

FIG. 8B is a cross-sectional view showing a structure in a channel length direction of the array shown in FIG. 8A;

FIG. 8C is a cross-sectional view showing a structure in a channel width direction of the array in the manufacturing process following that of FIG. 8A;

FIG. 8D is a cross-sectional view showing a structure in a channel length direction of the array shown in FIG. 8C;

FIG. 8E is a cross-sectional view showing a structure in a channel width direction of the array in the manufacturing process following that of FIG. 8C; and

FIG. 8F is a cross-sectional view showing a structure in a channel length direction of the array shown in FIG. 8E.

### DETAILED DESCRIPTION OF THE INVENTION

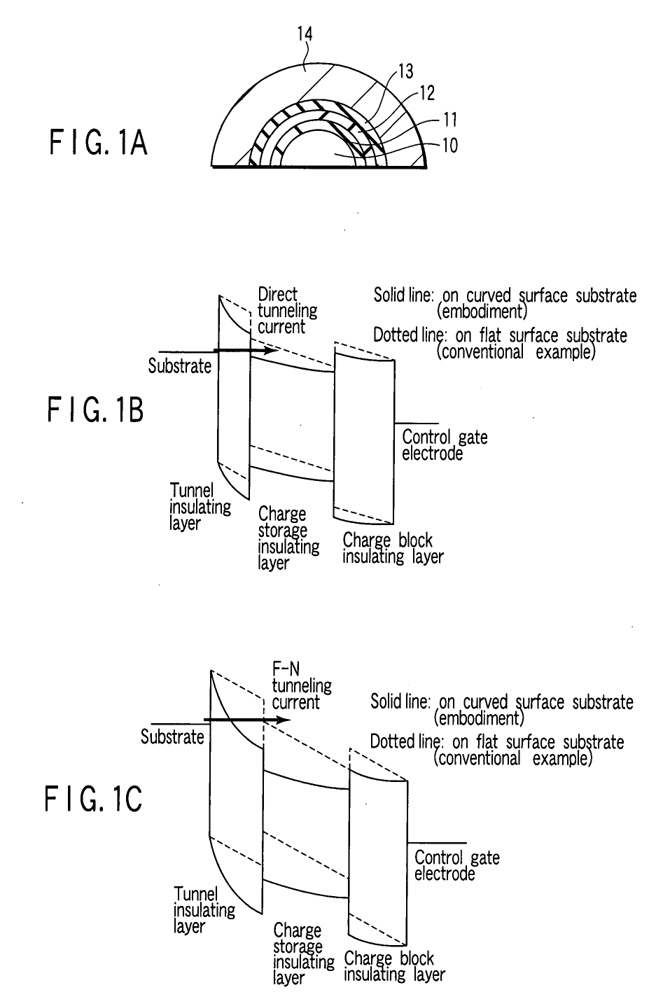

First, the basic concept of the present invention will be described with reference to FIGS. 1 to 3. FIG. 1A typically shows a structure of a MONOS type nonvolatile memory cell of the present invention. This memory cell has a structure in which a tunnel insulating layer 11, a charge storage insulating layer 12, a charge block insulating layer 13, and a control gate electrode 14 are sequentially formed on a convex curved surface portion of a semiconductor substrate 10. Hereinafter, this memory cell is referred to as a cell on the convex curved surface substrate.

FIGS. 1B and 1C schematically show energy band diagrams at the time of data writing to the memory cell of FIG. 1A. In the drawings, the case of a cell on the convex curved surface substrate is shown in solid lines, and the case of a cell on a conventional flat surface substrate is shown in broken lines for comparison. As compared with the cell on the flat surface substrate, in the cell on the convex curved surface substrate, an electric field in the vicinity of the substrate is intensive, and an electric field in the vicinity of the control gate electrode is weak. In particular, because the memory cell of the present invention has the charge storage layer serving as an insulator, an electric potential in the charge storage layer falls. Therefore, an electric field in the charge block insulating layer is sufficiently weaker than that in the tunnel insulating layer. Accordingly, a charge transfer between the substrate and the charge storage insulating layer is easy, and a charge transfer between the charge storage insulating layer and the control gate electrode is difficult. As a result, it is possible to carry out data writing/data erasing operations at low voltage or at high speed.

In FIG. 1B, the film thickness of the tunnel insulating layer is typically 2 to 3 nm, and data writing/data erasing operations are carried out by making a direct tunneling current flow in the tunnel insulating layer. Here, the direct tunneling current means an electric conduction mechanism in which charge in a substrate (electrons in this case) is directly transferred to a conduction band of the charge storage insulating layer.

Moreover, as shown in FIG. 1C, by making the film thickness of the tunnel insulating layer as thick as 4 to 10 nm which is the same level as the film thickness of the charge block insulating layer, it is possible to greatly increase an electric current flowing in the tunnel insulating layer 11 more than an electric current flowing in the charge block insulating layer 13. Therefore, it is possible to store charge in the charge storage insulating layer by making an F-N tunneling current flow in the tunnel insulating layer. As a result, it is possible to carry out data writing/data erasing operations. Here, the F-N tunneling current means an electric conduction mechanism in which charge in a substrate (electrons in this case) is once transferred to a conduction band of the tunnel insulating layer, and thereafter, it is transferred to a conduction band of the charge storage insulating layer.

Because the charge storage insulating layer 12 is sandwiched at the both interfaces by the thick potential barriers in the structure of the memory cell, it is possible to dramatically improve the data-retention characteristic as compared with a conventional MONOS type nonvolatile memory cell. Therefore, it is possible to store a large quantity of charge in the charge storage insulating layer 12, which makes it possible to set a threshold voltage of the memory cell transistor to a great number of levels, and the memory cell is suitable for a memory cell intended for multi-level operations.

Note that the structure of the memory cell in the present invention is not limited to a concentric cylindrical type in which a substrate surface of a portion facing the charge storage insulating layer 12 has a convex curved surface in section in one direction, and may be a concentric spherical type in which a substrate surface of a portion facing the charge storage insulating layer 12 has a convex curved surface in sections in two directions perpendicular to one another. Here, in the concentric spherical type, the curvatures of the sections in two directions may be different from one another. In this case, in the structure of the concentric cylindrical type cell, it is easy to form the cell, which has an effect of reducing dispersion in the memory cell characteristic caused by a variation in cell shapes. In contrast thereto, in the concentric spherical type cell structure, a difference in electric fields in the vicinity of the substrate and in the vicinity of the control gate electrode is made greater by providing a slight curvature on the substrate surface. Therefore, there is an effect by which it is possible to efficiently achieve the improvements in the data-retention characteristic and the data writing/data erasing characteristics.

Note that the “concentric cylindrical type/concentric spherical type” in the present application means not only the shapes of concentric cylinder/concentric sphere with constant curvatures, but also a convex prominent curved surface and a convex protruding curved surface, such as a shape in which a curvature is partially varied, shapes of eccentric cylinder/eccentric sphere, and the like. Further, the concentric cylindrical type/concentric spherical type is not necessarily curved surfaces at the atomic level, and for example, any curved surface which is generally curved as seen by a scanning electron microscope suffices to obtain the effect of the present application.

Further, in FIG. 1A, there is shown the case in which the film thicknesses of the tunnel insulating layer 11, the charge storage insulating layer 12, and the charge block insulating layer 13 are substantially uniform. However, it is not limited to this case, and the same effect can be obtained even when the film thicknesses are partially varied. However, in order to avoid a malfunction in the memory by stabilizing the memory cell characteristic, the respective film thicknesses are preferably uniform.

Moreover, the structure of the memory cell of the present invention may be formed such that the entire substrate surface of the portion facing the charge storage insulating layer 12 is not necessarily a convex curved surface region, and the structure has an effect of improving the data writing/data erasing characteristics and the data-retention characteristic as long as the substrate is partially a convex curved surface region. However, when a part of the convex shape of the substrate of the portion facing the charge storage insulating layer 12 is a flat region, the effect of improving the characteristics described above is reduced. Further, when the data writing/data erasing operations are carried out in an F-N tunnel system such that the film thickness of the tunnel insulating layer is made as thick as that of the charge block insulating film, it is difficult to carry out charge storage on the flat surface region, and a threshold shift of the cell transistor is reduced. Therefore, a cell structure in which the entire substrate surface of a portion facing the charge storage insulating layer 12 is a convex curved surface is preferable.

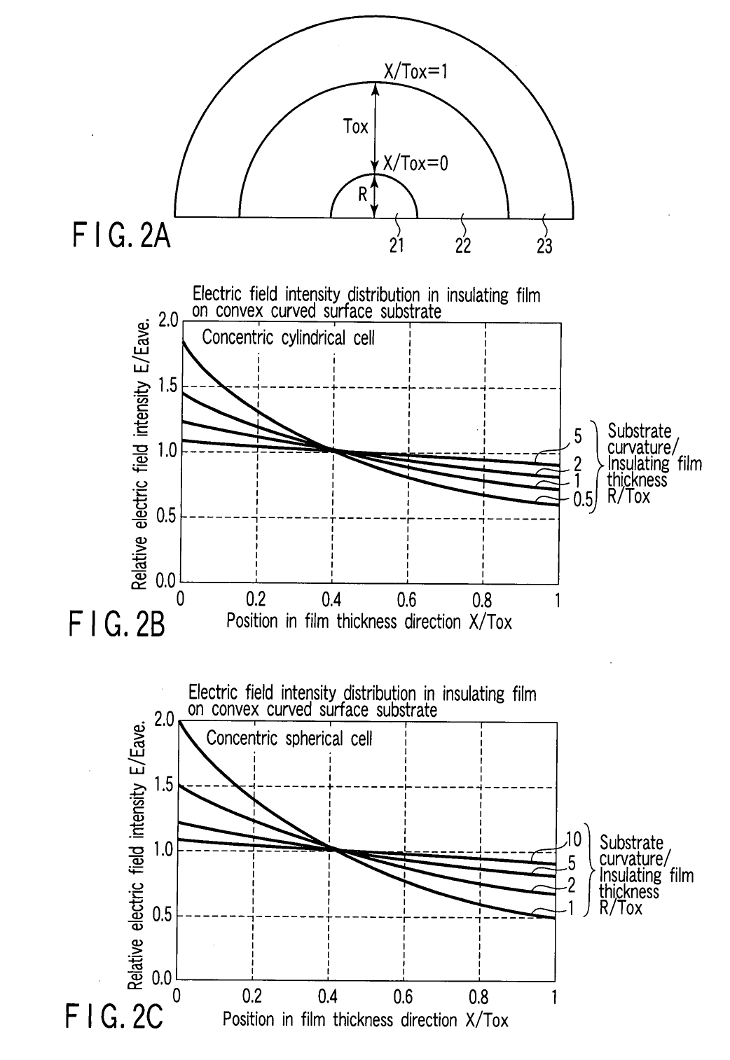

Here, for the purpose of reference, there will be described results in which electric field intensity in the insulating film between the conductors has been calculated when a potential difference is provided between curved surface conductors 21 and 23. At this time, as shown in FIG. 2A, given that a curvature of the inner conductor 21 (curvature of the substrate) is expressed by R, a distance between the conductors (film thickness of the insulating film 22) is expressed by Tox, and an electric field when the curvature R of the conductor is infinite is Eave, a relationship between a relative electric field intensity E/Eave and a relative position X/Tox in a film thickness direction, was examined.

FIG. 2B shows a relationship between a relative position X/Tox in a film thickness direction (axis of abscissa) and a relative electric field intensity E/Eave (axis of ordinate) in the case of a ratio of a substrate curvature and an insulating film thickness R/Tox=5, 2, 1, and 0.5 in the concentric cylindrical type cell.

Further, FIG. 2C shows a relationship between X/Tox and E/Eave in the case of a ratio of a substrate curvature and an insulating film thickness R/Tox=10, 5, 2, and 1 in the concentric spherical type cell.

In the both cases of FIGS. 2B and 2C, it is clear that E/Eave becomes stronger as X/Tox approaches the substrate, and E/Eave becomes weaker as X/Tox approaches the opposed electrode. Further, it is clear that a difference between the electric fields in the insulating film becomes greater as R/Tox is made smaller. Moreover, a difference between the electric fields in the insulating film in the concentric spherical type cell is greater than that in the concentric cylindrical type cell in the case of the same R/Tox.

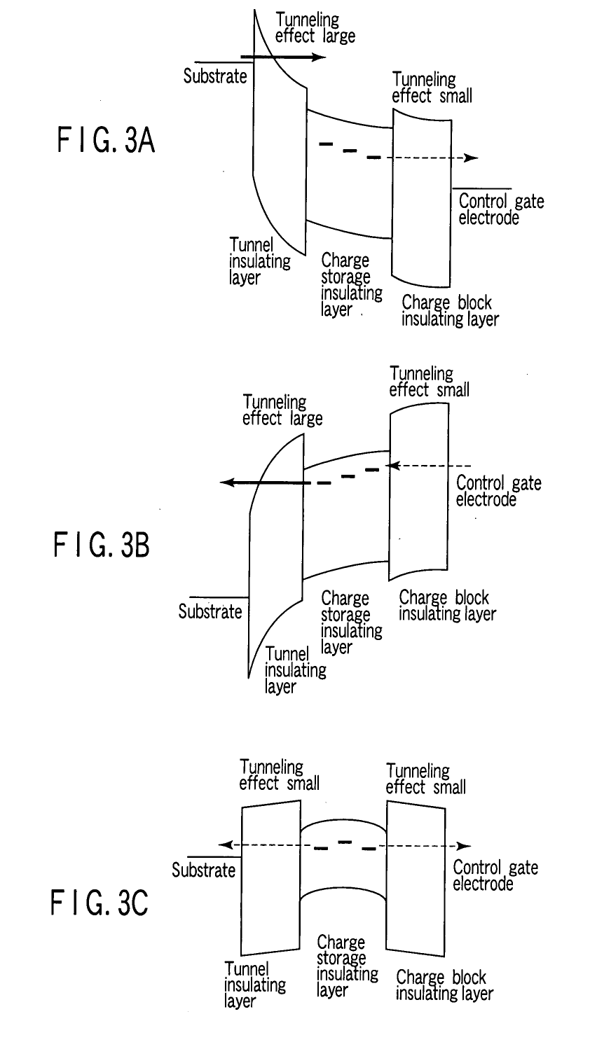

Next, operations of the memory cell of FIG. 1A will be described with reference to the energy band diagrams shown in FIGS. 3A to 3C. FIG. 3A shows an energy band diagram at the time of data writing to the memory cell of FIG. 1A. In a data writing operation, a high voltage is applied between the semiconductor substrate (the silicon semiconductor substrate in the present example) 10 and the control gate electrode 14, and a tunneling current (an F-N tunneling current in the present example) is made to flow in the tunnel insulating layer (the silicon oxide film in the present example) 11, thereby storing charge at an electric charge trap level (displayed by the short crossbars in the drawing) in the charge storage insulating layer (the silicon nitride film in the present example) 12. Namely, when a positive bias is applied to the control gate electrode 14 with respect to the substrate 10, the charge in the substrate is injected into the charge storage insulating layer 12 through the tunnel insulating layer 11, and the charge is trapped at the electric charge trap level in the charge storage insulating layer 12. At this time, an electric field is generated in the charge block insulating layer 13 as well. However, as shown in FIGS. 2B and 2C, because the electric field in the charge block insulating layer 13 is weaker than the electric field in the tunnel insulating layer 11, the charge in the charge storage insulating layer 12 is hard to escape toward the control gate electrode side. Namely, it is possible to efficiently store the charge in the charge storage insulating layer 12 by utilizing the fact that the tunneling effect in the tunnel insulating layer 11 is greater than that in the charge block insulating layer 13. As a result, it is possible to realize a “writing state” in which a threshold voltage of the transistor of the memory cell is shifted in the positive direction by applying a low voltage or at a high speed.

FIG. 3B shows an energy band diagram at the time of data erasing from the memory cell of FIG. 1A. In a data erasing operation, a negative bias is applied to the control gate electrode 14 with respect to the substrate 10, and the charge trapped at the electric charge trap level in the charge storage insulating layer 12 is discharged toward the substrate side through the tunnel insulating layer 11. At this time, an electric field is generated in the charge block insulating layer 13 as well. However, as shown in FIGS. 2B and 2C, because the electric field in the charge block insulating layer 13 is weaker than the electric field in the tunnel insulating layer 11, the charge in the control gate electrode 14 is hard to be injected into the charge storage insulating layer 12. Namely, it is possible to efficiently discharge the charge in the charge storage insulating layer 12 to the substrate side by utilizing the fact that the tunneling effect in the tunnel insulating layer 11 is greater than that in the charge block insulating layer 13. As a result, it is possible to realize an “erasing state” in which a threshold voltage of the transistor of the memory cell is shifted in the negative direction by applying a low voltage or at a high speed.

FIG. 3C shows an energy band diagram in a data-retention state in which data writing has been carried out to the memory cell of FIG. 1A, and the memory cell has been left as it is. During the time in which the cell onto which data writing has been carried out is left as it is (in a data-retention state), a so-called self electric field is generated due to the stored electric charge in the charge storage insulating layer 12, and the stored electric charge intends to escape toward the silicon substrate side and the control gate electrode side. This escape of electric charge can be avoided by sandwiching the charge storage insulating layer 12 with the tunnel insulating film 11 and the charge block insulating film 13 having high potential barriers. In particular, provided that a film thickness of the tunnel oxide film is made as thick as 4 to 10 nm, and data writing/data erasing operations in an F-N tunnel system are used, the tunneling effect due to a self-electric field is made extremely small, which makes it possible to realize an excellent data-retention characteristic.

As described above, in accordance with the MONOS type nonvolatile memory cell of the present invention, by making the substrate surface of the portion facing the charge storage insulating layer 12 a convex curved surface, it is possible to greatly vary a potential difference applied to the tunnel insulating layer 11 and the charge block insulating layer 13, and it is possible to greatly change electric field distributions, i.e., the tunneling effects in the both, which makes it possible to obtain an effect of providing a great difference between the tunneling effects. As a result, it is possible to reduce operating voltages for data writing/data erasing, or to accelerate operation speeds of data writing/data erasing. Moreover, provided that a film thickness of the tunnel insulating layer is made as thick as 4 to 10 nm, and data writing/data erasing operations in an F-N tunnel system are used, it is possible to realize an excellent data-retention characteristic.

Hereinafter, the present invention will be described in accordance with embodiments with reference to the drawings. At the time of describing, portions which are in common over all the drawings are denoted by common reference numerals.

### FIRST EMBODIMENT

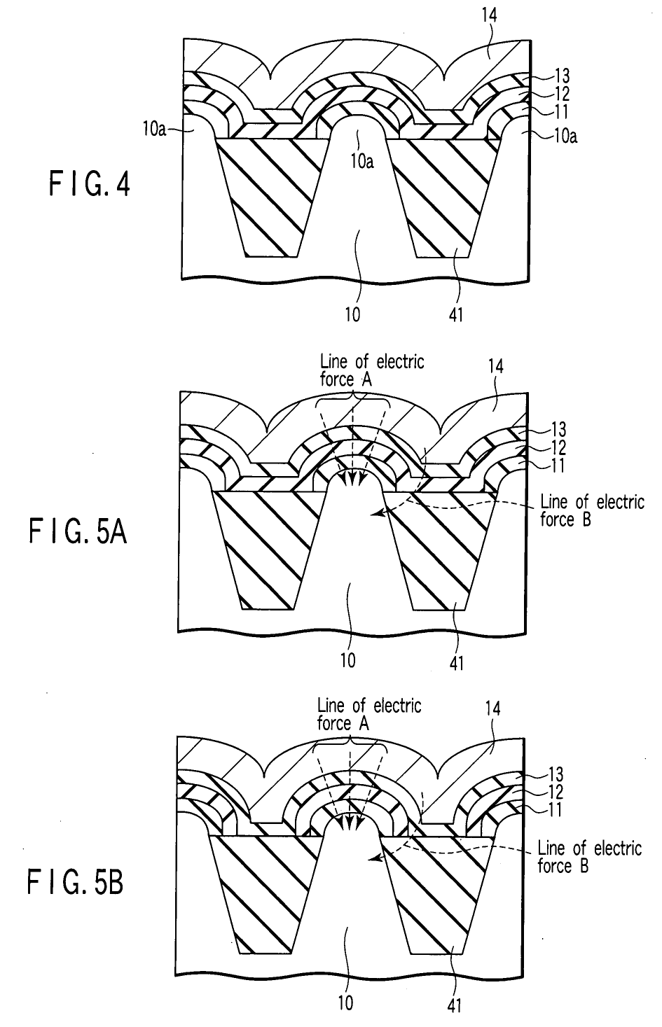

FIG. 4 shows a cross-sectional structure in a channel width direction (in a word line direction) of a memory cell in a MONOS nonvolatile memory having an array of a concentric cylindrical MONOS type memory cell according to a first embodiment.

In this memory cell, an isolation insulating film 41 formed of a silicon oxide film or the like is selectively provided on the surface of a semiconductor substrate 10 formed from semiconductor silicon or the like, and element regions sandwiched by the isolation insulating film 41 are projected to be convex curved surface portions 10a. Then, a charge storage insulating layer 12 formed of a silicon nitride film or the like is provided so as to sandwich a tunnel insulating layer 11 formed of a silicon oxide film or the like on the convex curved surface portions 10a of the substrate. In the present example, the substrate surface of portions facing the charge storage insulating layer 12 has convex curved surfaces in section in one direction. Moreover, a control gate electrode 14 formed of phosphorus-doped polycrystalline silicon or the like is provided so as to sandwich a charge block insulating layer 13 formed of a silicon oxide film or the like on the charge storage insulating layer 12.

Here, a thickness of the tunnel insulating layer 11 is generally 4 to 10 nm, a thickness of the charge storage insulating layer 12 is generally 1 to 20 nm, a thickness of the charge block insulating layer 13 is generally 4 to 10 nm, and a curvature of the convex curved surface portion 10a is generally less than or equal to 100 nm. Here, provided that a thickness of the tunnel insulating layer 11 is set to 4 to 10 nm, and data writing/data erasing operations are carried out in an F-N tunnel system, a data-retention characteristic is improved, which is preferable.

Further, as shown in FIG. 2B, a ratio R/Tox between an equivalent film thickness Tox of the laminated insulating film (the equivalent film thickness determined on the basis of capacitance supposing that a dielectric constant is a value of the tunnel insulating layer; more specifically, Tox is defined by ∈ₒₓ/C, where ∈ₒₓ is a dielectric constant value of the tunnel insulating layer and C is a capacitance value of the film per unit area) and a curvature R of the convex curved surface portion 10a is preferably less than or equal to 2. In accordance therewith, an electric field in the vicinity of the interface at the charge injection side is increased by 20% or more, and charge injection efficiency is increased hundredfold or more. Moreover, R/Tox is preferably less than or equal to 1. In accordance therewith, an electric field in the vicinity of the interface at the charge injection side is increased by 40% or more, and charge injection efficiency is increased ten-thousandfold or more. Provided that R/Tox is set in this way, operations at low voltages or high-speed operations are possible, and moreover, data writing/data erasing in an F-N tunnel system are possible, which dramatically improves the data-retention characteristic.

Further, the array of the MONOS type memory cell according to the present embodiment has the feature that the charge storage insulating layer 12 is connected among adjacent cells at least in the cross sectional direction transverse to the convex curved surface portion. In an array having such a structure, there is no need to carry out isolation of the charge storage insulating layer 12 among adjacent cells. Therefore, there can be obtained not only an effect of easily manufacturing the array, but also the following effect.

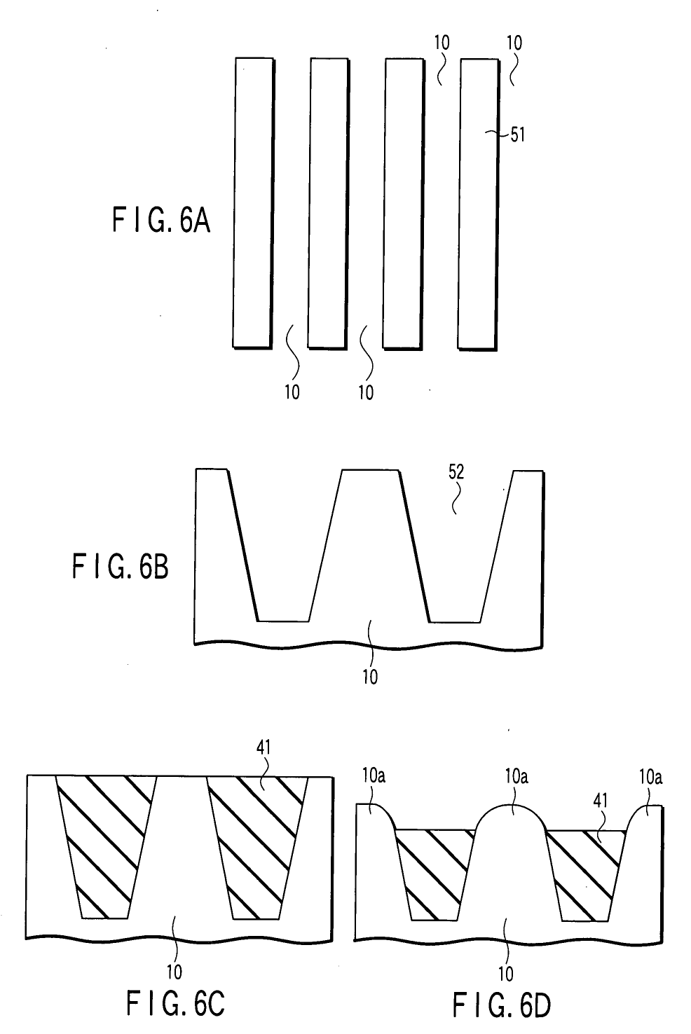

FIG. 5A shows an array of the MONOS type memory cell according to the present embodiment in which the charge storage insulating layer 12 is connected among adjacent cells, and FIG. 5B shows an array of the MONOS type memory cell according to a reference example in which the charge storage insulating layer 12 is isolated among adjacent cells. When the cell transistor is turned on, a positive bias is applied to the control gate electrode, and as shown in FIGS. 5A and 5B, an electric potential on the surface portion of the substrate is modulated to turn the channel on by generating a “line of electric force A”. At this time, because a “line of electric force B” is generated at a side wall portion at the side of the isolation insulating film of the substrate, there occurs a problem that a threshold voltage of the cell transistor is reduced when a channel of the side wall portion is turned on first. In particular, because the laminated insulating film between the substrate and the control gate electrode in the MONOS type memory cell is thicker than that of a normal MOS transistor, working of a “line of electric force A” is weak, which makes it easy to bring about the above-described problem.

For example, in the case of a structure in which the charge storage insulating layer is not connected among adjacent cells as shown in FIG. 5B, the working of a “line of electric force B” is made unignorable as compared with the working of a “line of electric force A”, which makes it easy to bring about the above-described problem. Namely, a threshold voltage is reduced depending on conditions such as a dopant impurity concentration in the side wall portion of the substrate, a fixed quantity of electric charge, and the like.

In contrast thereto, in the case of a structure in which the charge storage insulating layer is connected among adjacent cells as shown in FIG. 5A, the working of a “line of electric force B” is negligible as compared with the working of a “line of electric force A”. Therefore, the problem that a threshold voltage is reduced is not brought about, and the structure is a preferable structure.

Note that, because the above-described problem becomes particularly prominent when the tunnel insulating layer is made as thick as 4 to 10 nm as in the present embodiment, the effect in the case of employing the structure of FIG. 5A is profound.

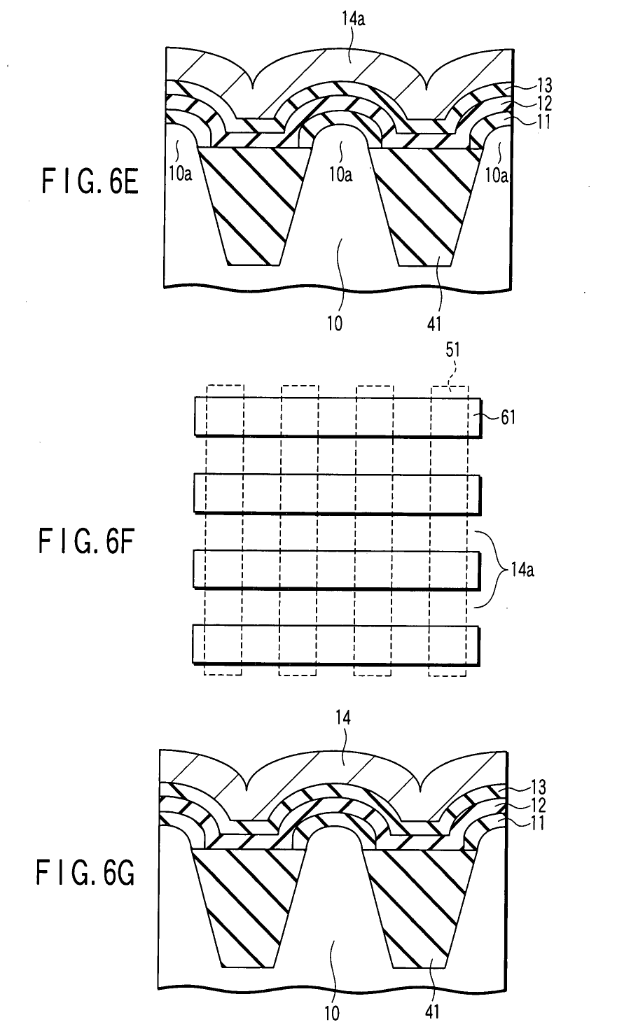

Next, a method for manufacturing an array of the memory cell shown in FIG. 4 will be described with reference to FIGS. 6A to 6H. FIGS. 6A and 6F show plan views of the array in a manufacturing process, and FIGS. 6B to 6D, and FIGS. 6E and 6G show cross-sectional views in a channel width direction (in a word line direction) of the memory cell, and FIG. 6H shows a cross-sectional structure in a channel length direction (in a bit line direction) of the memory cell.

First, as shown in FIG. 6A, an element region pattern 51 formed of, for example, a silicon nitride film is formed on the silicon semiconductor substrate 10 such that a width and an interval thereof are respectively made to be about 50 nm. Next, grooves 52 for isolation are formed on the surface of the silicon substrate 10 as shown in FIG. 6B by using a reactive ion etching (RIE) method by using the element region pattern 51 as a mask, and thereafter, the element region pattern 51 is removed.

Next, as shown in FIG. 6C, an isolation insulating film 41 formed of, for example, a silicon oxide film is embedded into the grooves for isolation, and thereafter, the isolation insulating film overflowing the grooves is removed by using a chemical mechanical polish (CMP) method.

Next, an RIE is carried out under the condition that an etching selectivity of the element isolation film 41 with respect to the silicon substrate 10 is about double, and as shown in FIG. 6D, the surface portions of the isolation insulating film 41 are made to withdraw and the corner portions of the side wall portions at the side of the silicon substrate which are exposed are etched, thereby forming the convex curved surface portions 10a. It should be noted that where the etching selectivity is greater than 1, the shape shown in FIG. 6D is obtained. In order to obtain a shape that permits the present invention to effectively produce its advantages, it is desirable that the etching selectivity be approximately 2.

Next, as shown in FIG. 6E, a silicon oxide film with a thickness of 6 nm which will be the tunnel insulating layer 11 is formed by using a radical oxidation method on the entire surface. At this time, the silicon substrate 10 is set in a radical oxidation reactor, and heated to be about 600° C. Then, radical oxidizing species are generated by supplying microwave power of about 3 kW in a mixed gas atmosphere (for example, at a mixing ratio of 1:100) of oxygen with a pressure of 100 Pa and argon, and this is held for about 120 seconds, thereby forming the tunnel insulating layer 11.

Moreover, a silicon nitride film having an electric charge trap level with a thickness of 10 nm which will be the charge storage insulating layer 12 is formed by using a chemical vapor deposition (CVD) method. Moreover, a silicon oxide film with a thickness of 8 nm which will be the charge block insulating layer 13 is formed by using a CVD method. After the three-layer laminated insulating film is provided in this way, a conductive layer 14a formed of phosphorus-doped polycrystalline silicon is formed on the entire surface by using a CVD method.

Next, as shown in FIG. 6F, a control gate electrode pattern 61 formed of, for example, a silicon oxide film is formed on the conductive layer 14a such that a width and an interval thereof are respectively made to be about 50 nm so as to be perpendicular to the element region pattern 51 described above with reference to FIG. 6A.

Next, the control gate electrode 14 is formed as shown in FIG. 6G by processing the conductive layer 14aby using the control gate electrode pattern 61 as a mask by using an RIE method, and thereafter, the control gate electrode pattern 61 is removed.

Next, as shown in FIG. 6H, diffusion layers 62 are formed on the substrate surface portions by using an ion implantation method by using the control gate electrode 14 as a mask. In accordance therewith, regions sandwiched by the diffusion layers 62 become channel regions. Thereafter, an interlayer insulation film 63 is formed on the entire surface, and wiring and the like are formed by using a well-known technique, thereby completing the array of the MONOS type nonvolatile memory. In a cross section that is transverse to the channel length direction (bit line direction) shown in FIG. 6H, the laminating insulating layer of the adjacent cells may be scattered. One of the tunnel insulating layer, the charge storage insulating layer, and the charge block insulating layer, which constitute the laminating insulating layer, may be scattered.

Note that, in order to realize a stable cell characteristic of the MONOS type memory, it is an important factor that the film thicknesses of the respective layers of the laminated insulating layer are uniform. Therefore, the tunnel insulating layer 11 is preferably formed by a radical oxidization method in the first embodiment. The convex curved surface portion 10a is an aggregate of silicon crystals having various surface orientations, and an oxidation rate differs depending on a surface orientation of a silicon crystal. Accordingly, in the case where the tunnel insulating layer is formed by a normal thermal oxidation method, a cell in which the film thickness of the tunnel insulating layer is partially different is formed, and a charge injection rate is made uneven in the cell. Note that, when the tunnel insulating layer is formed by a CVD method, the quality in the film is inferior, which makes it impossible to obtain a satisfactory data-retention characteristic.

As described above, in the first embodiment, the dependency on a surface orientation of a silicon crystal is low due to the tunnel insulating layer 11 being formed by a radical oxidization method on the convex curved surface portions 10a. Thus, the uniformity of the film thicknesses is improved, and as a result, charge injection rates at the time of data writing/data erasing are made uniform at the respective portions in the cell. Accordingly, it is possible to avoid the problems of an increase in S factors in the cell transistor characteristic and an increase in dispersion among cells after data writing/data erasing, thereby realizing a memory cell in which a malfunction is hard to occur.

Note that, in the above-described first embodiment, the radical oxidization method is an oxidization method using radical oxidizing species. Then, as radical oxidizing species, there are exemplified oxygen atoms in the excitation state or the ground state, hydroxyl (OH) in the excitation state or the ground state, oxygen molecules in the excitation state, water molecules, ozone molecules, and the like in the excitation state, and species which are electrically neutral and are charged with electricity. In the present embodiment, the radical oxidizing species such as oxygen atoms, oxygen molecules, and the like in the excitation state, have been generated by discharging a mixed gas of oxygen and argon as a microwave. However, the method for generating radical oxidizing species is not limited thereto, and a mixed gas may be a combination of another oxygen-containing gas and a noble gas, and further, hydroxyl or the like may be generated by mixing a hydrogen-containing gas such as a hydrogen gas or the like. Moreover, radical oxidizing species may be generated by another plasma technique such as a high-frequency (RF) discharge or the like. Further, an oxygen gas and a hydrogen gas are introduced into a reactor to be heated to react, and radical oxidizing species such as hydroxyl or the like may be generated in accordance therewith. Furthermore, as in a remote plasma method and an ozone oxidation method, a place in which radical oxidizing species are generated and a place in which the silicon substrate is set may be different from one another.

Note that, even when the tunnel insulating layer is formed by a radical nitridation method in place of a radical oxidation method, the same effect can be obtained. Here, the radical nitridation method is a nitridation method in which radical nitrogen is regarded as nitriding species. Then, as radical nitrogen, there are exemplified nitrogen atoms in the excitation state or the ground state, nitrogen molecules in the excitation state, nitric monoxide molecules in the excitation state, and the like, and species which are electrically neutral and are charged with electricity as well are included therein.

As a specific example of a radical nitridation method, there is a method in which radical nitriding species such as nitrogen molecules, nitrogen atoms, and the like in the excitation state are generated by discharging a nitrogen gas at a high frequency (RF), and the resultant species are reacted with the surface of the silicon substrate. However, it goes without saying that a method for generating radical nitriding species is not limited to the above-described example, and various modifications thereof are possible in the same way as the method for generating radical oxidizing species described above.

In the above-described embodiment, the film thickness of the tunnel insulating layer has been made to be 6 nm. However, when the tunnel insulating layer is formed from a silicon oxide film or a silicon nitride film, the film thickness may be set to be in the range of 4 to 10 nm. Here, the lower limit of the film thickness of the tunnel insulating layer is determined on the basis of an amount of threshold voltage variation of the cell transistor at the time of data-retention. In order to guarantee the data-retention for 10 years, it is necessary to suppress a threshold voltage variation of the cell transistor, corresponding to a total amount of the charge stored in the charge storage insulating layer and leaked through the tunnel insulating layer for 10 years, to be less than or equal to a predetermined allowable value (which is typically less than or equal to 0.1 V). An amount of the leakage of charge is determined on the basis of a direct-tunneling efficiency of the tunnel insulating layer as shown in FIG. 3C. In the case of the tunnel insulating layer formed from a silicon oxide film, the film thickness of 5 nm or more sufficiently reduces the direct-tunneling effect, and sufficiently guarantees a threshold voltage variation of 0.1 V or less for 10 years. Note that, even when the tunnel insulating layer is formed from a silicon oxynitride film, the film thickness of 5 nm or more can reduce the direct-tunneling effect, making it possible to guarantee a threshold voltage variation of 0.1 V or less for 10 years. Note that the above-described “to sufficiently guarantee” means a case of guaranteeing charge retention for 10 years in a harsh use condition such as, for example, in an uncontrolled state at a high temperature of 50° C. or more, or the like. In a case in which it is sufficient to guarantee charge retention for 10 years in a normal use condition, the film thickness of the tunnel insulating layer may be 4 nm or more.

On the other hand, the upper limit of the film thickness of the tunnel insulating layer is determined on the basis of an amount of threshold voltage variation of the memory cell transistor at the time of data writing/data erasing operations. A threshold voltage is varied due to a part of injected electric charge being trapped in the tunnel insulating layer by the writing/erasing operations. This electric charge trap is notably brought about as the tunnel film thickness becomes thicker. In the case of the tunnel insulating layer formed of a silicon oxide film, the film thickness of 10 nm or less sufficiently reduces an amount of electric charge trap, and sufficiently guarantees a threshold voltage variation of 0.1 V or less. Note that, even when the tunnel insulating layer is formed of a silicon oxynitride film, the film thickness of 10 nm or less reduces an amount of electric charge trap, and guarantees a threshold voltage variation of 0.1 V or less. Moreover, when the tunnel insulating layer is thick, operating voltages for data writing/data erasing are increased, which makes it difficult to miniaturize a device or to make a low consumption device, and therefore, it is not preferred to be made greater than 10 nm.

Further, in accordance with the manufacturing method of the first embodiment described above, there is provided a process of forming a tunnel insulating layer by a radical oxidation method or a radical nitridation method on convex curved surface portions formed on a surface of a semiconductor substrate, and of sequentially laminating a charge storage layer, a charge block insulating layer, and a conductive layer which will be a control gate electrode. In accordance therewith, charge injection is uniformly carried out in a cell, and it is possible to avoid a memory malfunction after data writing/data erasing.

Note that, in the above-described first embodiment, the case in which the substrate surface of the portion facing the charge storage insulating layer 12 has a convex curved surface in section in one direction has been described as an example. However, the entire surface of the substrate surface may not necessarily be a convex curved surface region, and as long as the substrate surface is partially a convex curved surface region, there is an effect of improving the data writing/data erasing characteristics, and the data-retention characteristic. However, when a part of the above-described substrate surface (for example, the top surface of the convex curved surface portion) is a flat surface region, the above-described effect is slightly reduced.

Further, a material of the charge storage insulating layer 12 may be the silicon nitride film or an insulation film having a dielectric constant value higher than that of the silicon nitride film, for example, a so-called high dielectric insulating film such as a hafnium film or the like, and a material of the charge block insulating layer 13 may be a silicon nitride film or an insulation film having a dielectric constant value higher than that of the silicon nitride film, for example, a so-called high dielectric insulating film such as an alumina film or the like.

Note that, in the present embodiment, the case in which the substrate surface has a convex curved surface in section in a channel width direction has been shown. However, it goes without saying that the same effect can be obtained even when the substrate surface has a convex curved surface in section in a channel length direction.

### SECOND EMBODIMENT

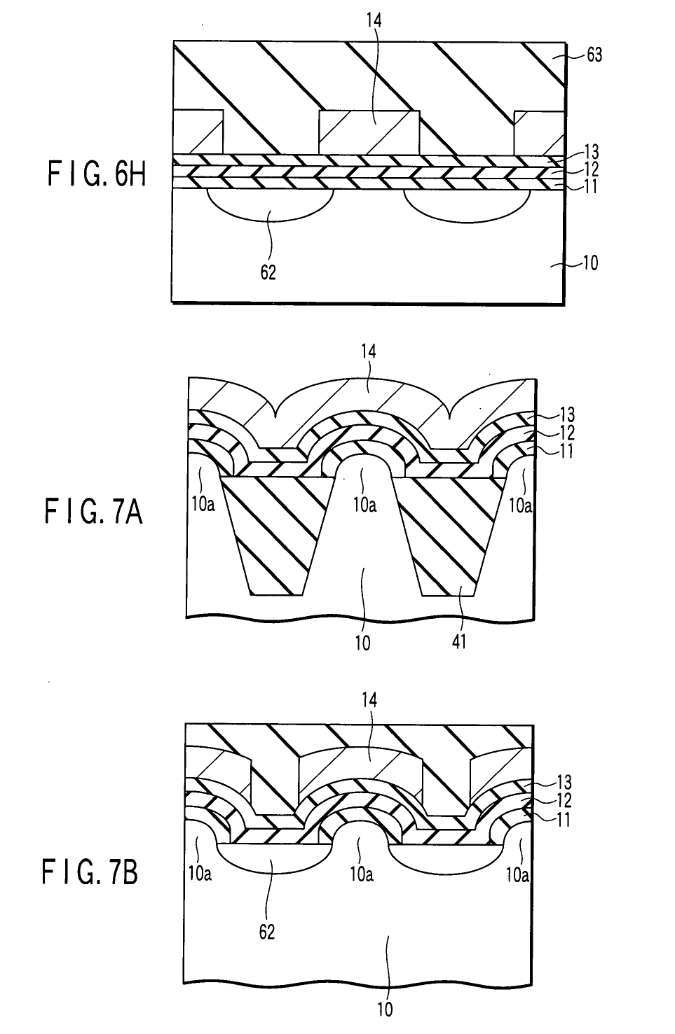

FIG. 7A shows a cross-sectional structure in a channel width direction (in a word line direction) of the memory cell in the MONOS type nonvolatile memory having an array of concentric spherical MONOS type memory cells according to a second embodiment. FIG. 7B shows a cross-sectional structure in a channel length direction (in a bit line direction) of the memory cell of FIG. 7A.

In this memory cell, an isolation insulating films 41 formed of a silicon oxide film or the like are provided in parallel on the surface of a semiconductor substrate 10 formed of semiconductor silicon or the like, and element regions sandwiched by the isolation insulating films 41 are projected to be convex curved surface portions 10a. In the present example, the substrate surface of the portion facing a charge storage insulating layer formed in the following process has convex curved surfaces in sections in two directions perpendicular to one another. Moreover, diffusion layers (drain/source regions) 62 are provided so as to be adjacent in a channel length direction at the element regions, and channel portions sandwiched by the diffusion layers are projected to be the convex curved surface portions 10a. Then, a charge storage insulating layer 12 formed of a silicon nitride film or the like is provided so as to sandwich a tunnel insulating layer 11 formed of a silicon oxide film or the like on the convex curved surface portions 10a. A control gate electrode 14 formed of phosphorus-doped polycrystalline silicon or the like is further provided thereon so as to sandwich a charge block insulating layer 13 formed of a silicon oxide film or the like.

A thickness of the tunnel insulating layer 11 is generally 4 to 10 nm, a thickness of the charge storage insulating layer 12 is generally 1 to 20 nm, a thickness of the charge block insulating layer 13 is generally 4 to 10 nm, and curvatures in sections in two directions of the convex curved surface portion 10a are generally less than or equal to 200 nm. Note that, when a thickness of the tunnel insulating layer 11 is set to 4 to 10 nm, and data writing/data erasing operations are carried out in an F-N tunnel system, the data-retention characteristic is improved, which is preferable.

Further, as shown in FIG. 2C, a ratio R/Tox between an equivalent film thickness Tox of the laminated insulating film formed of the tunnel insulating layer 11, the charge storage insulating layer 12, and the charge block insulating layer 13 (the equivalent film thickness determined on the basis of capacitance supposing that a dielectric constant is a value of the tunnel insulating layer; more specifically, Tox is defined by ∈ₒₓ/C, where ∈ₒₓ is a dielectric constant value of the tunnel insulating layer and C is a capacitance value of the film per unit area), and a curvature R of the substrate surface is preferably less than or equal to 5. In accordance therewith, an electric field in the vicinity of the interface at the charge injection side is increased by 20% or more, and charge injection efficiency is increased hundredfold or more. Moreover, R/Tox is preferably less than or equal to 2. In accordance therewith, an electric field in the vicinity of the interface at the charge injection side is increased by 40% or more, and charge injection efficiency is increased ten-thousandfold or more. When R/Tox is set in this way, operations at low voltages or high-speed operations are possible, and moreover, data writing/data erasing in an F-N tunnel system are possible, which dramatically improves the data-retention characteristic.

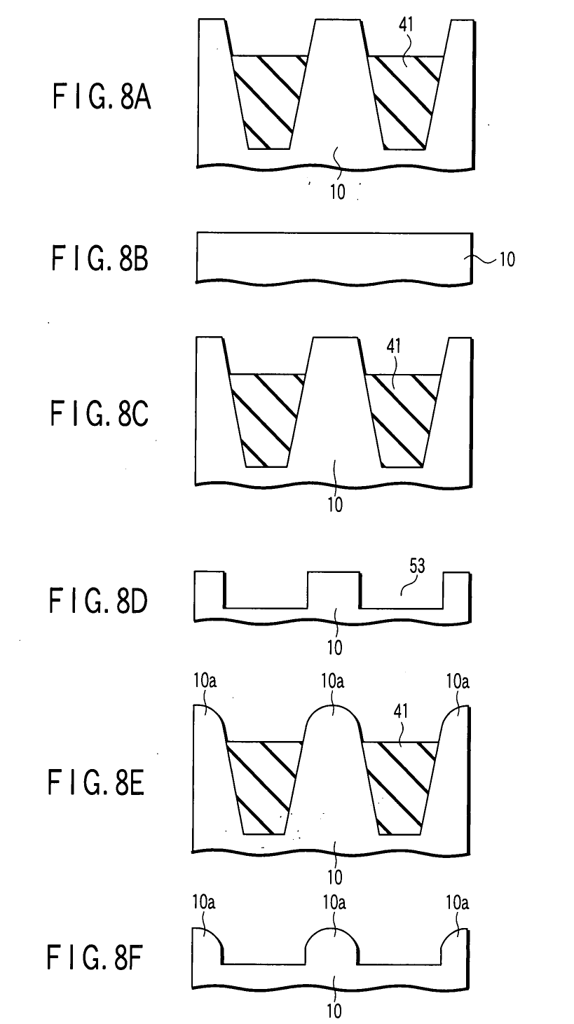

Next, a method for manufacturing an array of the memory cell shown in FIGS. 7A and 7B will be described with reference to FIGS. 8A to 8F. Here, FIGS. 8A, 8C, and 8E show a cross-sectional structure in a channel width direction (in a word line direction) of the memory cell, and FIGS. 8B, 8D, and 8F show a cross-sectional structure in a channel length direction (in a bit line direction) at the respective processes of FIGS. 8A, 8C, and 8E.

First, grooves for isolation are formed on the silicon substrate 10 by using the same method as that described above with reference to FIG. 6B in the first embodiment, and the isolation insulating films 41 formed of silicon oxide films are embedded therein. Next, as shown in FIGS. 8A and 8B, the surfaces of the isolation insulating films 41 are etched by a chemical such as diluted hydrofluoric acid or the like to be withdrawn by about 50 nm. Next, as shown in FIGS. 8C and 8D, an RIE is carried out onto the silicon by using a stripe mask in a channel length direction. After groove portions 53 of an iterative pattern with a depth of about 50 nm are formed on the protruded portion of the silicon substrate surface, the stripe mask is removed.

Next, as shown in FIGS. 8E and 8F, chemical dry etching (CDE) using chlorine radical or fluorine radical is carried out onto the entire surface such that the corner portions of the silicon are rounded. Then, the convex curved surface portions 10a having convex curved surfaces in sections in two directions perpendicular to one another are formed by removing the corner portions of the side wall portions at the side of the silicon substrate in a channel width direction and a channel length direction by etching. Thereafter, the MONOS type nonvolatile memory is completed by using the same method as that described above in the first embodiment.

Note that, in the second embodiment, the case in which the substrate surface of the portion facing the charge storage insulating layer 12 has convex curved surfaces in sections in two directions perpendicular to one another has been described as an example. However, the entire surfaces of the convex curved surface portions 10a may not necessarily be convex curved surface regions. As long as the surfaces of the convex curved surface portions 10a are partially convex curved surface regions, there is an effect of improving the data writing/data erasing characteristics and the data-retention characteristic. However, when some of the substrate surface is flat surface regions, for example, when the top surfaces of the convex curved surface portions 10a are flat, and only the side surface portions thereof are spherical shapes, the above-described effect is slightly reduced.

Further, a material of the charge storage insulating layer 12 may be the silicon nitride film or an insulation film having a dielectric constant value higher than that of the silicon nitride film, for example, a so-called high dielectric insulating film such as a hafnium film or the like, and a material of the charge block insulating layer 13 may be a silicon nitride film or an insulation film having a dielectric constant value higher than that of the silicon nitride film, for example, a so-called high dielectric insulating film such as an alumina film or the like.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A MONOS type nonvolatile memory cell comprising:
a semiconductor substrate having a convex curved surface portion;
a laminated insulating layer which is formed of a tunnel insulating layer with a thickness of 4 to 10 nm, a charge storage insulating layer, and a charge block insulating layer, which are sequentially laminated on the convex curved surface portion; and
a control gate electrode which is formed on the laminated insulating layer,
wherein the memory cell carries out data writing/data erasing operations by making an F-N tunneling current flow in the tunnel insulating layer.

2. The MONOS type nonvolatile memory cell according to claim 1, wherein a curvature of the convex curved surface portion is less than or equal to 200 nm.

3. The MONOS type nonvolatile memory cell according to claim 1, wherein, given that an equivalent film thickness of the laminated insulating layer is Tox, and a curvature of the convex curved surface portion of the semiconductor substrate is R, a ratio R/Tox of Tox and R is less than or equal to 2, the equivalent film thickness being determined on the basis of capacitance supposing that a dielectric constant is a value of the tunnel insulating layer.

4. The MONOS type nonvolatile memory cell according to claim 1, wherein, given that an equivalent film thickness of the laminated insulating layer is Tox, and a curvature of the convex curved surface portion of the semiconductor substrate is R, a ratio R/Tox of Tox and R is less than or equal to 1, the equivalent film thickness being determined on the basis of capacitance supposing that a dielectric constant is a value of the tunnel insulating layer.

5. The MONOS type nonvolatile memory cell according to claim 1, wherein the convex curved surface portion has a concentric cylindrical shape having a convex curved surface in section in one direction of the semiconductor substrate.

6. The MONOS type nonvolatile memory cell according to claim 1, wherein the convex curved surface portion has a concentric spherical shape having convex curved surfaces both in sections in two directions perpendicular to one another of the semiconductor substrate.

7. The MONOS type nonvolatile memory cell according to claim 1, wherein the tunnel insulating layer being formed from one of a silicon oxide film and a silicon oxynitride film.

8. The MONOS type nonvolatile memory cell according to claim 1, wherein the charge storage insulating layer being formed from one of a silicon nitride film and an insulation film having a dielectric constant value higher than that of the silicon nitride film.

9. The MONOS type nonvolatile memory cell according to claim 1, wherein the charge block insulating layer being formed from one of a silicon nitride film and an insulation film having a dielectric constant value higher than that of the silicon nitride film.

10. A MONOS type nonvolatile memory comprising:
an array which is formed of a plurality of MONOS type nonvolatile memory cells adjacent to one another, each memory cell has a convex curved surface portion formed on a semiconductor substrate, and a laminated insulating layer which is formed of a tunnel insulating layer with a thickness of 4 to 10 nm, a charge storage insulating layer, and a charge block insulating layer, which are sequentially laminated on the convex curved surface portion, and the array carries out data writing/data erasing operations by making an F-N tunneling current flow in the tunnel insulating layer; and
a control gate electrode which is formed to continue over the laminated insulating film of adjacent ones of the memory cells.

11. The MONOS type nonvolatile memory according to claim 10, wherein the charge storage insulating layer being connected among said plurality of memory cells at least in a cross sectional direction transverse to the convex curved surface portion.

12. The MONOS type nonvolatile memory according to claim 10, wherein a curvature of the convex curved surface portion being less than or equal to 200 nm.

13. The MONOS type nonvolatile memory according to claim 10, wherein, given that an equivalent film thickness of the laminated insulating layer is Tox, and a curvature of the convex curved surface portion is R, a ratio R/Tox of Tox and R is less than or equal to 2, the equivalent film thickness being determined on the basis of capacitance supposing that a dielectric constant is a value of the tunnel insulating layer.

14. The MONOS type nonvolatile memory according to claim 10, wherein, given that an equivalent film thickness of the laminated insulating layer is Tox, and a curvature of the convex curved surface portion is R, a ratio R/Tox of Tox and R is less than or equal to 1, the equivalent film thickness being determined on the basis of capacitance supposing that a dielectric constant is a value of the tunnel insulating layer.

15. The MONOS type nonvolatile memory according to claim 10, wherein the convex curved surface portion has a concentric cylindrical shape having a convex curved surface in section in one direction of the semiconductor substrate.

16. The MONOS type nonvolatile memory according to claim 10, wherein the convex curved surface portion has a concentric spherical shape having convex curved surfaces both in sections in two directions perpendicular to one another of the semiconductor substrate.

17. A method for manufacturing a MONOS type nonvolatile memory comprising:
forming a plurality of convex curved surface portions on a semiconductor substrate;
forming a tunnel insulating layer with a thickness of 4 to 10 nm on said each convex curved surface portion by one of a radical oxidation method and a radical nitridation method; and
sequentially laminating a charge storage insulating layer, a charge block insulating layer, and a conductive layer of a control gate electrode on the tunnel insulating layer.

18. The method for manufacturing a MONOS type nonvolatile memory according to claim 17, wherein the charge storage insulating layer being formed to continue over said plurality of convex curved surface portions.

19. The method for manufacturing a MONOS type nonvolatile memory according to claim 17, wherein
forming a plurality of grooves on the semiconductor substrate;
forming insulating films in said plurality of grooves;
etching the semiconductor substrate and the insulating films under the condition that an etching selectivity of the insulating films with respect to the semiconductor substrate is about double to expose side wall portions of the semiconductor substrate by withdrawing surface portions of the insulating films and to form said plurality of convex curved surface portions by etching corner portions of the exposed side wall portions of the semiconductor substrate.

20. The method for manufacturing a MONOS type nonvolatile memory according to claim 19, wherein the etching is carried out that curvatures of said plurality of convex curved surface portions are made to be less than or equal to 200 nm.
